(19) United States
(12) Patent Application Publication
(10) Pub. No.: US 2003/0011381 A1
(43) Pub. Date: Jan. 16, 2003

(54) Container for fluid material

(76) Inventor: George Arndt, Twin Lake, MI (US)

Correspondence Address: THOMAS HOXIE, NOVARTIS CORPORATION, PATENT AND TRADEMARK DEPT, 564 MORRIS AVENUE, SUMMIT, NJ, 079011027

(21) Appl. No.: 10/176,846

(22) Filed: Jun. 21, 2002

Related U.S. Application Data
(60) Provisional application No. 60/300,585, filed on Jun. 22, 2001.

(51) Int. Cl. G01R 27/00

(52) U.S. Cl. 324/537; 324/718

(57) ABSTRACT

The present invention provides a defect detecting system and a container therefor. The container has a chamber body for storing an electrically conductive fluid material. The container is produced from a unitary multilayer film and has an electrode with one end of the electrode exposed to the inside and the other end exposed to the outside of the chamber. The multiple layer film has a thermoplastic layer and an electrically conductive layer, and the thermoplastic layer and the electrode are adapted to contact the fluid material. The electrode is hermetically affixed to the container and electrically separated from the electrically conductive layer.

Containers for transporting liquid and semi-liquid materials include gable-top containers, and multilayer film containers, e.g., pouches and bags. A gable-top container has an inner covering film layer of thermoplastic and additionally may have a barrier layer under the film layer. Multilayer film containers are produced from a film laminate which contains at least one thermoplastic layer and at least one barrier layer. The barrier layer, which is typically produced from a flexible metal, e.g., aluminium, or a barrier thermoplastic polymer, e.g., ethylene-vinyl alcohol copolymer, largely prevents oxygen from reaching the material placed in the container. The oxygen barrier layer provides extended shelf life for the packaged material.

Small manufacturing defects, such as pinholes and voids, are not easily detectable and can lead to reduced shelf life. In addition to manufacturing defects, small defects can be formed from handling of the container. When a container holding an aseptically filled food material has or develops pinholes, the food material spoils rapidly. There remains a need for a system to detect or continuously detect and a method for detecting or continuously detecting the integrity of a container.

### SUMMARY OF THE INVENTION

There is provided a container having a chamber body for storing an electrically conductive fluid material. The container is produced from a unitary multilayer film and has an electrode with one end of the electrode exposed to the inside and the other end exposed to the outside of the chamber. The multiple layer film has a thermoplastic layer and an electrically conductive layer, and the thermoplastic layer and the electrode are adapted to contact the fluid material. The electrode is hermetically affixed to the container and electrically separated from the electrically conductive layer. Additionally provided is a container suitable for detecting defects therein, which container has a chamber body for storing an electrically conductive fluid material. The container is produced from a unitary multilayer film that has an electrically non-conductive polymer layer and an electrically conductive polymer layer. The present invention also provides a method for detecting defects using the present container. The term “electrically non-conductive” as used herein indicates a level of electrical conductivity that cannot be readily detected by a simple current detection system such as a volt ohm meter.

The container of the present invention can be a rigid or flexible container. When a rigid container is desired, a thick mulilayer film is used to produce a rigid container, e.g., a self supporting structure. The container of the present invention is highly useful as a part of a quality control system.

### DETAILED DESCRIPTION OF THE INVENTION

The present invention provides a multilayer film container that has a monitoring system. The monitoring system can be used to detect defects that can lead to loss and/or destruction of the material placed in the container. As discussed above, small defects in a container, such as pinholes and voids, are difficult to detect, and such defects can be formed while manufacturing and also while handling and using the container. The present invention utilizes electrical conductivity of a layer in a multilayer film to detect and monitor physical integrity of a container.

Multilayer films have been used to produce containers, e.g., pouches and bags, for storing and carrying liquid and semi-liquid materials, e.g., food and drink. Typically, such multilayer films have a barrier layer which significantly reduces oxygen permeability. A barrier layer can be formed from a thermoplastic polymer having high barrier properties, e.g., ethylene-vinyl alcohol copolymer or vinylidene chloride, or a metal, e.g., aluminium or copper foil. A multilayer film has at least two layers. The first layer is a thermoplastic polymer layer that is produced from a thermoplastic polymer and the second layer is the barrier layer. In general, a second thermoplastic layer is placed or laminated over the barrier layer to protect the barrier layer. The first and second thermoplastic layers are produced from a thermoplastic polymer, which is typically used in packaging applications, and the two layers can be produced from one polymer or from different polymers. Suitable thermoplastic polymers for the first and second layers include polyolefins, polyesters, polyvinyl chloride, copolymers of acrylic acids, fluoropolymers and the like. Exemplary suitable polymers include very low density polyethylene, linear low density polyethylene, low density polyethylene, high density polyethylene, polypropylene, polyesters, e.g., polyethylene terephthalate, ethylene-vinyl acetate, polyvinyl chloride and copolymers thereof. As is known in the art, many additional layers can be added to the multilayer film depending on the objectives of each use of the film. Such additional layers include an adhesive layer between the thermoplastic polymer layer and the barrier layer.

When a container of the present invention is produced from a multilayer film having a non-metallic or non-conductive barrier layer, the multilayer film needs to include an electrically conductive polymer layer. Electrically conductive polymers are known in the art. They include conductively modified polymers and intrinsically conductive polymers. Exemplary conductively modified polymers include thermoplastic polymers in which carbon black, zinc oxide, cuprous iodide, colloidal silver or colloidal graphite is dispersed. Intrinsically conductive polymers include polyacetylene; polyaniline; polycarbazole; polyfuran; polyheteroarylenevinylene, in which the heteroarylene group is thiophene, furan or pyrrole; polyisothionaphene; polyparaphenylene; polyparaphenylene sulphide; polyparaphenylene vinylene; polyperinaphthalene; polyphthalocyanine; polypyrrole; polyquinoline; polythiophene; and mixtures and copolymers thereof.

As an alternative embodiment of the present invention, a multilayer film without a barrier layer can be used to produce a container, if barrier properties are not required in an application of the container. If a multilayer film without a barrier layer is utilized, the multilayer film must have an electrically conductive polymer layer.

A container of the present invention can be formed from a multilayer film by various known processes including heat-sealing processes and thermoforming processes. When a heat-sealing process is used to produce a container, as is known in the art, the selected polymer for the outer layer of the multilayer film, which contacts the material to be placed in the container, should not only be chemically non-reactive to the material, but also be amenable to a heat sealing process. As an example of producing a heat sealed package, a pouch can be formed from a multilayer film by cutting two sheets of a multilayer film, abuttingly placing the first layers of two sheets, and applying heat to near or at the edges of the film sheets to produce adjoined seams by thermally joining the two first layers. Optionally, a tie layer, e.g., ethylene-vinyl acetate, ethylene acrylic acid copolymer, can be used to facilitate the heat-sealing process.

In accordance with the present invention the container has at least one electrode. One end of the electrode is exposed in the chamber of the container, and the other end of the electrode is exposed to the outside of the container. The electrode is affixed to the container such that the electrode is hermetically sealed, but does not make electrical contact with the conductive layer of the multilayer film. A suitable electrode can have any shape that is adapted to and suitable for each application, including a shape of a wire or strip. Care should be given to ensure that the shape of the electrode does not cause defects in the container while manufacturing and using the container. A suitable electrode can be produced from various electrically conductive materials, including metals, e.g., aluminium, brass, copper, steel, stainless steel and the like, and electrically conductive polymers, e.g., conductive polymers discussed above. When selecting an appropriate material for the electrode, one important consideration is the potential chemical interaction between the electrode material and the fluid material that is to be stored in the container. As one embodiment of the invention, the container can have two or more separately placed electrodes. The two electrodes can be used to test the electrical circuitry of the container. For example, the two electrodes are used to ensure that the fluid material placed in the container conducts electricity and are separated from the electrically conductive layer of the miltilayer film.

The container can be tested for its physical integrity by using an electrical current detecting system. Any device that can detect open and close electrical circuits can be employed as the electrical current detecting system. A volt ohm meter or a regulator (e.g., Holiday Detector) can be used. Another suitable detecting system is a simple low voltage circuitry that includes a battery and a light emitting diode or a buzzer that are serially connected. In addition, the current detecting system can be a remote sensing system. A conventional wireless communication system, e.g., radio frequency communication system, can be utilized to adapt the present detecting system into a remote sensing system. Such a remote system can easily be connected to a computer system to continuously monitor and to analyze the physical integrity of the container. To test the physical integrity of a container, the container is filled with an electrically conductive fluid, e.g., aqueous food material that is to be placed in the container, and then one of the two poles of the detecting system is connect to the exposed end of the electrode from the outside of the container and the other pole of the detecting system is connected to the metal barrier layer or the electrically conductive polymer layer of the multilayer film that forms the container. If there is a pinhole or void in the film, the electrical current will flow through the closed system which is formed by the food material connecting the electrode and the electrically conductive layer of the multilayer film exposed by the defect. If there is no defect in the container, the inner polymer layer of the multilayer film that contacts the food material acts as an electrical insulator, preventing the detection system to form a closed circuit.

As an illustrative embodiment of the present invention, a container is produced by a heat-sealing process. A three-layer film, which has two low density polyethylene outer film layers and a middle aluminium barrier layer, is cut to two rectangular sheets of approximately equal size. The two sheets of the cut film is placed one over the other, and a thin copper wire is place between the film sheets at one edge. The three connecting edges, including the edge containing the wire, are heat sealed to form adjoined seams using a conventional heat sealing apparatus, leaving one edge unsealed. The length of the wire used is longer than the width of the heat sealed seams, and the wire is separated from the aluminium barrier layers of the pouch by the adjoined polyethylene layer. The unsealed opening is used to introduce a fluid material that is to be stored in the pouch, e.g., juice, and the opening is subsequently sealed to produce a hermetically sealed pouch containing the fluid material. A simple electrical current detecting system, having a low voltage battery and a serially connected piezoelectric buzzer, is connected to the pouch. One lead of the detecting system is connected to the electrode and the other lead is connected to the aluminium layers of the pouch. The aluminium layers are exposed by gently scraping the outer polyethylene layers of the pouch, and then the exposed aluminium surface is connected to the lead using a clip. If there are voids or pinholes in the pouch, the buzzer sounds since a closed circuit is formed. In accordance with the present invention, the exposed electrically conductive layer can be formed during the manufacturing process of the multilayer film such that attaching the detection system is simplified. Moreover, when different panels of the container are not electrically connected to each other, as in a pouch, each panel has its own electrically conductive layer exposed to the outside such that each panel can be connected to the current detecting system. Such compartmentalized panel connection to the current detection system can be advantageously used to specifically locate the panel with a defect.

The containers of the present invention are suitable for storing and transporting liquid and semi-liquid materials, for example, liquid food materials, e.g., juice, soup and syrups; semi-liquid food materials, e.g., fruit and vegetable purees; and liquid medical supplies, e.g., nutritional supplements, provided that the fluid materials are electrically conductive. The containers can be adapted and used as various packaging and storing containers, including retort packages, hot-fill packages and aseptic packages. The containers and the detection system of the present invention can be used as an essential part of a quality control system for the manufacture of the container and the packaged product. In addition, the container and the detection system can be used as a continuous monitoring system to ensure the integrity or sterility of the packaged product.

What is claimed is:

1. A container comprising a chamber body for storing an electrically conductive fluid material, said container comprising a unitary multilayer film and an electrode having two ends, said chamber body comprising said multilayer film and having an inside and an outside, and said multilayer film comprising a thermoplastic layer and an electrically conductive layer, wherein said thermoplastic layer and said electrode are adapted to contact said fluid material, one end of said electrode is exposed to said inside and the other end of said electrode is exposed to said outside of said chamber, and said electrode is hermetically affixed to said container and electrically separated from said electrically conductive layer.

2. The container of claim 1 wherein said chamber is formed by heat sealing edges of said multilayer film and said electrode is located in one of the heat sealed edges.

3. The container of claim 1 wherein said electrically conductive layer is an aluminium foil.

4. The container of claim 1 wherein said multilayer film comprises a first polyolefin layer, an aluminium layer and a second polyolefin layer.

5. A method for detecting defects of a container for storing an electrically conductive fluid material, said container comprising a chamber body for storing an electrically conductive fluid material, said container comprising a unitary multilayer film and an electrode having two ends, said chamber body comprising said multilayer film and having an inside and an outside, and said multilayer film comprising a thermoplastic layer and an electrically conductive layer, wherein said thermoplastic layer and said electrode are adapted to contact said fluid material, one end of said electrode is exposed to said inside and the other end of said electrode is exposed to said outside of said chamber, and said electrode is hermetically affixed to said container and electrically separated from said electrically conductive layer, said method comprising:
a) connecting said electrode to one pole of an electrical current detection system having two electrically opposite poles,
b) connecting said electrically conductive layer to the other pole of said electrical current detection system, and
c) detecting absence or presence of electrical current between said electrode and said electrically conductive layer.

6. A defect detection system container comprising a chamber body for storing an electrically conductive fluid material and an electrical current detection system, wherein said container comprises a unitary multilayer film and an electrode having two ends, said chamber body comprises said multilayer film and has an inside and an outside, said multilayer film comprises a thermoplastic layer and an electrically conductive layer, said thermoplastic layer and said electrode are adapted to contact said fluid material, wherein one end of said electrode is exposed to said inside and the other end of said electrode is exposed to said outside of said chamber, said electrode is hermetically affixed to said container and electrically separated from said electrically conductive layer, and said electrical current detection system is serially connected to said electrode and said electrically conductive layer.

7. The container of claim 6 wherein said chamber is formed by heat sealing edges of said multilayer film and said electrode is located in one of the heat sealed edges.

8. The container of claim 7 wherein said electrically conductive layer is an aluminium foil.

9. The container of claim 7 wherein said multilayer film comprises a first polyolefin layer, an aluminium layer and a second polyolefin layer.

10. The container of claim 6 wherein said electrical current detection system comprises a battery, and a diode or a piezoelectric buzzer.

11. A container comprising a chamber body for storing an electrically conductive fluid material, said container comprising a unitary multilayer film, said chamber body comprising a multilayer film, and said multilayer film comprising an electrically non-conductive polymer layer and an electrically conductive polymer layer.

12. The container of claim 11 wherein said electrically conductive polymer comprises a conductively modified polymer or an intrinsically conductive polymer.

13. The container of claim 12 wherein said electrically conductive polymer comprises polyaniline.
